(19) United States
(12) Patent Application Publication
(10) Pub. No.: US 2023/0071985 A1
(43) Pub. Date: Mar. 9, 2023

(54) SUBSTRATE PROCESSING APPARATUS AND SUBSTRATE PROCESSING METHOD USING THE SAME

(71) Applicant: Samsung Electronics Co., Ltd., Suwon-si (KR)

(72) Inventors: Woorim LEE, Suwon-si (KR); Sunggil KANG, Hwaseong-si (KR); Minhyoung KIM, Seoul (KR); Inseong KIM, Hwaseong-si (KR); Seokyoung PARK, Suwon-si (KR); Sangjin AN, Suwon-si (KR); Inhye JEONG, Changnyeong-gun (KR); Kyusik CHOI, Suwon-si (KR)

(73) Assignee: Samsung Electronics Co., Ltd., Suwon-si (KR)

(21) Appl. No.: 17/749,800

(22) Filed: May 20, 2022

(30) Foreign Application Priority Data
Aug. 24, 2021 (KR) 10-2021-0111702
Oct. 5, 2021 (KR) 10-2021-0131720

(51) Int. Cl. H01J 37/32; H01L 21/02; H01L 21/3065; H01L 29/66

(52) U.S. Cl. CPC H01J 37/3244; H01L 21/0259; H01L 21/02532; H01L 21/3065; H01L 29/66545; H01L 29/66742; H01J 37/32724; H01J 37/32477; H01J 37/32834; H01J 2237/334

(57) ABSTRACT

A substrate processing apparatus includes first to fourth sets of inner surfaces that at least partially define a plasma forming region, a gas supply region, gas mixing region, and a substrate processing region, respectively, where the substrate processing apparatus is configured to form a plasma within the plasma forming region, supply a process gas from the gas supply region to the plasma forming region, form an etchant in the gas mixing region based on recombination of radicals supplied from the plasma forming region, and process a substrate based on the etchant within the substrate processing region; a shower head between the gas mixing region and the substrate processing region and configured to supply the etchant to the substrate processing region; a coating layer covering a surface of the shower head and including nickel (Ni) containing phosphorus (P); and a heater configured to control a surface temperature of the shower head.

### CROSS-REFERENCE TO RELATED APPLICATIONS

This application claims benefit of priority to Korean Patent Application No. 10-2021-0131720, filed on Oct. 5, 2021 in the Korean Intellectual Property Office, and Korean Patent Application No. 10-2021-0111702, filed on Aug. 24, 2021 in the Korean Intellectual Property Office, the disclosures of each of which are incorporated herein by reference in their entirety.

### BACKGROUND

Example embodiments of the present inventive concepts relate to a substrate processing apparatus and a substrate processing method using the same, and more particularly, to a substrate processing apparatus using plasma and a substrate processing method using the same.

To manufacture a semiconductor device, a series of processes such as deposition, etching, and cleaning may be performed. These processes may be performed through a substrate processing apparatus such as a deposition apparatus, an etching apparatus, or a cleaning apparatus having a process chamber. For example, in the case of an etching process using a plasma processing technique, a substrate processing apparatus etching a material layer on a substrate using plasma such as capacitively coupled plasma (CCP) or inductively coupled plasma (ICP) or etching a material layer on a substrate using a remote plasma source (RPS) outside a process chamber has been used.

### SUMMARY

Some example embodiments of the present inventive concepts provide a substrate processing apparatus having improved etch selectivity and a substrate processing method using the same.

According to some example embodiments of the present inventive concepts, a semiconductor device may include a first set of inner surfaces that at least partially define a plasma forming region, wherein the substrate processing apparatus is configured to form a plasma within the plasma forming region, a second set of inner surfaces that at least partially define a gas supply region, wherein the substrate processing apparatus is configured to supply a process gas from the gas supply region to the plasma forming region, a third set of inner surfaces that at least partially define a gas mixing region, wherein the substrate processing apparatus is configured to form an etchant in the gas mixing region based on recombination of radicals supplied from the plasma forming region to the gas mixing region; a fourth set of inner surfaces that at least partially define a substrate processing region, wherein the substrate processing apparatus is configured to process a substrate based on the etchant within the substrate processing region; a shower head between the gas mixing region and the substrate processing region, the shower head configured to supply the etchant to the substrate processing region; a coating layer covering a surface of the shower head, the coating layer including nickel (Ni) containing phosphorus (P); and a heater configured to control a surface temperature of the shower head.

According to some example embodiments of the present inventive concepts, a semiconductor device may include a first set of inner surfaces that at least partially define a plasma forming region, wherein the substrate processing apparatus is configured to form a plasma within the plasma forming region; a second set of inner surfaces that at least partially define a gas mixing region, wherein the substrate processing apparatus is configured to form an etchant in the gas mixing region based on recombination of radicals supplied from the plasma forming region to the gas mixing region; a third set of inner surfaces that at least partially define a substrate processing region, wherein the substrate processing apparatus is configured to process a substrate based on the etchant within the substrate processing region; a shower head between the gas mixing region and the substrate processing region, the shower head configured to supply the etchant to the substrate processing region; and a coating layer covering at least a portion of a surface of the shower head, the portion of the surface of the shower head including an upper surface of the shower head, the coating layer containing phosphorus (P).

According to some example embodiments of the present inventive concepts, a substrate processing apparatus may include a process chamber including one or more sets of inner surfaces that at least partially define a plasma processing space within the process chamber; a gas supply configured to supply gas into the process chamber; a power supply configured to form a plasma in the process chamber; a substrate support member located in the process chamber, the substrate support member configured to support a substrate in the process chamber; a shower head on the substrate support member in the process chamber; at least one gas distribution plate on the shower head in the process chamber; and a coating layer covering at least a portion of one or more surfaces of the shower head, the at least one gas distribution plate, and the process chamber, the coating layer including nickel (Ni) containing phosphorus (P).

According to some example embodiments of the present inventive concepts, a substrate processing method may include supplying a first process gas containing fluorine (F) to a plasma forming region within a process chamber, the plasma forming region at least partially defined by a first set of inner surfaces of the process chamber; performing a first plasma forming process that includes forming plasma based on applying RF power to the plasma forming region subsequently to supplying the first process gas to the plasma forming region; drawing one or more gases out of the process chamber; loading a substrate onto a substrate support member that is located in a substrate processing region in the process chamber; supplying a second process gas containing fluorine (F) to the plasma forming region; performing a second plasma forming process that includes forming plasma based on applying RF power to the plasma forming region subsequently to supplying the second process gas to the plasma forming region; and processing the substrate based on supplying an etchant including fluorine (F₂) formed in the process chamber to the substrate processing region through a shower head of the process chamber. A surface of the shower head may be covered with a coating layer, the coating layer including nickel (Ni) containing phosphorus (P). Fluorine radicals formed in the first plasma forming process may be adsorbed to a surface of the coating layer and are recombined with fluorine radicals formed in the second plasma forming process to form the etchant containing fluorine (F₂).

### BRIEF DESCRIPTION OF THE DRAWINGS

The above and other aspects, features, and advantages of the present inventive concepts will be more clearly understood from the following detailed description, taken in conjunction with the accompanying drawings, in which:

FIG. 1 is a cross-sectional view illustrating a substrate processing apparatus according to some example embodiments of the present inventive concepts;

FIG. 2 is an enlarged view illustrating a portion of a substrate processing apparatus according to some example embodiments of the present inventive concepts;

FIGS. 3A, 3B, 3C, and 3D are enlarged views illustrating a portion of a substrate processing apparatus according to some example embodiments of the present inventive concepts;

FIGS. 4A and 4B are cross-sectional views illustrating a substrate processing apparatus according to some example embodiments of the present inventive concepts;

FIG. 5 is a flowchart illustrating a substrate processing method according to some example embodiments of the present inventive concepts;

FIGS. 6A and 6B are views illustrating a substrate processing method according to some example embodiments of the present inventive concepts;

FIG. 7 is a graph illustrating a substrate processing method according to some example embodiments of the present inventive concepts;

FIGS. 8A and 8B are graphs illustrating a substrate processing method according to some example embodiments of the present inventive concepts;

FIG. 9 is a cross-sectional view illustrating a semiconductor device manufactured using a substrate processing apparatus and a substrate processing method according to some example embodiments of the present inventive concepts;

FIG. 10 is a flowchart illustrating a method of manufacturing a semiconductor device according to some example embodiments of the present inventive concepts; and

FIGS. 11A, 11B, and 11C are views illustrating processes of a method of manufacturing a semiconductor device in order according to some example embodiments of the present inventive concepts.

### DETAILED DESCRIPTION

Hereinafter, some example embodiments of the present inventive concepts will be described as follows with reference to the accompanying drawings.

In some example embodiments, the terms such as “upper,” “upper surface,” “lower,” “lower surface,” “side,” and the like, are used with reference to the drawings, and may be varied depending on the direction in which a component is disposed unless otherwise indicated.

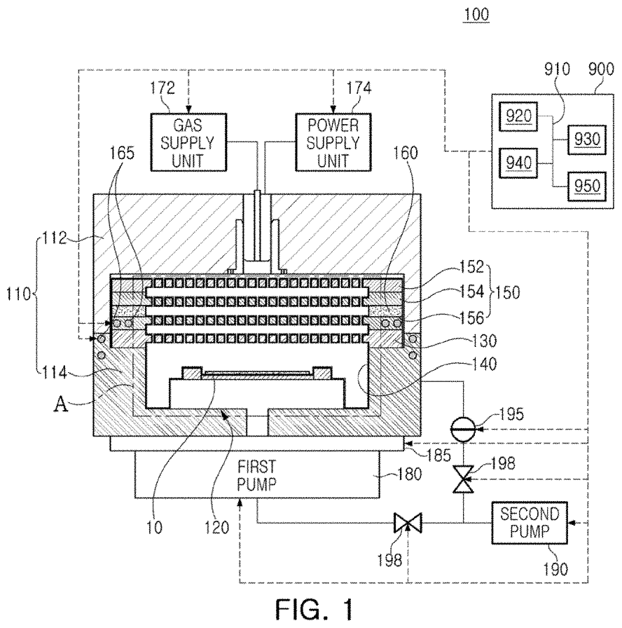

In the description of FIGS. 1 to 11C, the same reference numerals are used for substantially the same components, and duplicate descriptions of the corresponding components will be omitted. Also, similar reference numerals are used for similar components throughout various drawings of the present inventive concepts.

It will be understood that when an element such as a layer, film, region, or substrate is referred to as being “on” another element, it may be directly on the other element or intervening elements may also be present. For example, when an element is on another element and intervening elements are present, the element may be on and further spaced apart from (e.g., isolated from direct contact with) the other element, also referred to as being “indirectly” on the other element. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

As described herein, when an operation is described to be performed “by” performing additional operations, it will be understood that the operation may be performed “based on” the additional operations, which may include performing said additional operations alone or in combination with other further additional operations.

FIG. 1 is a cross-sectional view illustrating a substrate processing apparatus according to some example embodiments.

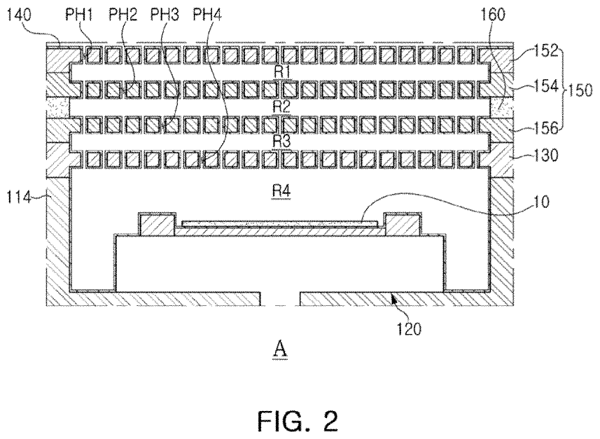

FIG. 2 is an enlarged view illustrating a portion of a substrate processing apparatus according to some example embodiments, illustrating portion “A” in FIG. 1.

Referring to FIGS. 1 and 2, a substrate processing apparatus 100 may include a process chamber 110, a substrate support 120, a shower head 130, a coating layer 140, a gas distribution unit 150 including first to third gas distribution plates 152, 154, and 156, a gas supply unit 172, a power supply unit 174, and first and second pumps 180 and 190. The substrate processing apparatus 100 may further include a dielectric member 160, a heating unit 165 (also referred to herein interchangeably as a heater, heater device, heating apparatus, or the like), first and second pressure regulators 185 and 195, and valves 198.

Also, as illustrated in FIG. 2, the substrate processing apparatus 100 may include a gas supply region R1 including a region disposed between the first gas distribution plate 152 and the second gas distribution plate 154 (e.g., such that the first gas distribution plate 152 and the second gas distribution plate 154 may be understood to at least partially define the gas supply region R1 between the first gas distribution plate 152 and the second gas distribution plate 154, for example between opposing surfaces thereof), a plasma forming region R2 between the second gas distribution plate 154 and the third gas distribution plate 156 (e.g., such that the second gas distribution plate 154 and the third gas distribution plate 156 may be understood to at least partially define the plasma forming region R2 between the second gas distribution plate 154 and the third gas distribution plate 156, for example between opposing surfaces thereof), a gas mixing region R3 between the third gas distribution plate 156 and the shower head 130 (e.g., such that the third gas distribution plate 156 and the shower head 130 may be understood to at least partially define the gas mixing region R3 between the third gas distribution plate 156 and the shower head 130, for example between opposing surfaces thereof), and a substrate processing region R4 below the shower head 130 (e.g., such that the shower head 130 may be understood to at least partially define the substrate processing region R4, for example between the shower head 130 and the substrate support 120, for example between opposing surfaces thereof).

In some example embodiments, the substrate processing apparatus (e.g., substrate processing apparatus 100) may be understood to include various sets of inner surfaces that each at least partially define one or more of the aforementioned regions R1 to R4. For example, the substrate processing apparatus 100 (e.g., the process chamber 110) may be understood to include a first set of inner surfaces (e.g., opposing surfaces of the second and third gas distribution plates 154 and 156) that at least partially define the plasma forming region R2, wherein the substrate processing apparatus 100 is configured to form a plasma within the plasma forming region R2. In another example, the substrate processing apparatus 100 (e.g., the process chamber 110) may be understood to include a second set of inner surfaces (e.g., opposing surfaces of the first and second gas distribution plates 152 and 154) that at least partially define a gas supply region R1, wherein the substrate processing apparatus 100 is configured to supply a process gas from the gas supply region R1 to the plasma forming region R2. In another example, the substrate processing apparatus 100 (e.g., the process chamber 110) may be understood to include a third set of inner surfaces (e.g., opposing surfaces of the third gas distribution plate 156 and the shower head 130) that at least partially define a gas mixing region R3, wherein the substrate processing apparatus 100 is configured to form an etchant in the gas mixing region R3 based on recombination of radicals supplied from the plasma forming region R2 to the gas mixing region R3. In another example, the substrate processing apparatus 100 (e.g., the process chamber 110) may be understood to include a fourth set of inner surfaces (e.g., a bottom surface of the shower head 130, one or more surfaces of the lower chamber 114 and/or substrate support 120, etc.) that at least partially define a substrate processing region R4, wherein the substrate processing apparatus 100 is configured to process a substrate 10 based on the etchant within the substrate processing region R4.

In some example embodiments, one or more, or all, of the regions R1 to R4 may be referred to as a plasma processing space. For example, the substrate processing region R4 may be referred to as a plasma processing space. In another example, regions R1 to R4 may be collectively referred to as a plasma processing space. Accordingly, the substrate processing apparatus 100 may, in some example embodiments, be understood to include a process chamber 110 that includes one or more sets of inner surfaces that at least partially define a plasma processing space within the process chamber.

The substrate processing apparatus 100 may be implemented as a dry etching apparatus performing an etching process for the substrate 10 provided on the substrate support 120 using plasma. The substrate support 120, also referred to herein as a substrate support member, may be understood to be located in the processing chamber 110 (e.g., within the substrate processing region R4) and may be understood to be configured to support (e.g., structurally support, support the weight of, etc.) one or more substrates 10 in processing chamber 110 (e.g., in the substrate processing region R4) such that the one or more substrates 10 are on (e.g., the one or more substrates 10 are on, the one or more substrates 10 transfer their respective weights to, etc.) the substrate support 120. In some example embodiments, the substrate processing apparatus 100 may be implemented as a dry cleaning apparatus performing etch cleaning. In some example embodiments, including the example embodiments shown in FIGS. 1 and 2, the substrate processing apparatus 100 may use a capacitively coupled plasma (CCP) method, but the plasma forming method of the substrate processing apparatus 100 is not limited thereto. The substrate 10 may be, for example, a silicon wafer used for manufacturing a semiconductor device such as a semiconductor integrated circuit (IC).

The process chamber 110 may provide a space in which plasma is formed and a space in which an etching process is performed. The process chamber 110 may provide a sealed internal space in which the substrate 10 is processed. The process chamber 110 may include an upper chamber 112 surrounding the space in which the plasma is formed and a lower chamber 114 surrounding the space in which an etching process is performed, but the configuration of the process chamber 110 is not limited thereto. A passage through which the substrate 10 is loaded and unloaded may be provided on one side of the process chamber 110. Alternatively, the substrate 10 may be loaded and unloaded while the lower chamber 114 is separated from the upper chamber 112. The process chamber 110 may be formed of a metal material, and may include, for example, aluminum (Al) or an alloy thereof. In some example embodiments, one or more inner surfaces of the lower chamber 114, the substrate support 120, and/or the shower head 130 may at least partially define the substrate processing region R4.

The substrate support 120, also referred to herein as a substrate support unit, a substrate support member, or the like, may be disposed (e.g., located) in a lower portion of the process chamber 110, and may support the substrate 10 while the substrate 10 is being processed. The substrate support 120 may include, for example, an electrostatic chuck, a heater, and a susceptor. For example, the substrate support 120 may be configured to support the substrate 10 by vacuum adsorption by the electrostatic chuck. The substrate support 120 may perform a function of controlling the temperature of the substrate 10 by heating or cooling the substrate 10. In some example embodiments, the substrate support 120 may be configured to move up and down.

The gas supply unit 172 (also referred to herein as a gas supply, including for example at least one container of gas which may be pressurized or unpressurised, a gas flow control valve configured to be adjusted and/or actuated to control a supply of gas from the at least one container, or the like) may supply a process gas necessary for plasma generation, and the process gas may be supplied to the plasma forming region R2 through the gas supply region R1. The gas supply region R1 may include at least a portion of a region between the gas supply unit 172 and the second gas distribution plate 154. The power supply unit 174 (also referred to herein interchangeably as a power supply, power supply device, power generator, plasma generator, or the like) may supply power used for plasma generation. For example, the power supply unit 174 may apply radio frequency (RF) power in the form of electromagnetic waves, having a particular (or, alternatively, predetermined) frequency and intensity, to the second gas distribution plate 154. For example, the power supply unit 174 may be an RF power supply (e.g., RF power generator, RF plasma generator, RF plasma generator/amplifier, etc.). The third gas distribution plate 156 may be electrically connected to the ground. Accordingly, the plasma forming region R2 may be formed between the second gas distribution plate 154 and the third gas distribution plate 156.

The gas distribution unit 150 may supply the process gas supplied from the gas supply unit 172 to the shower head 130 disposed therebelow. The gas distribution unit 150 may include a plurality of first to third gas distribution plates 152, 154, and 156. The first and third gas distribution plates 152 and 156 may function as electrode plates to which power for plasma generation is applied as described above. The first to third gas distribution plates 152, 154, and 156 may include a plurality of first to third through-holes PH1, PH2, and PH3 to allow gas or plasma to pass therethrough, respectively. The first to third gas distribution plates 152, 154, and 156 may include a metal material, such as, for example, aluminum (Al) which may be easily machined. In some example embodiments, the number of gas distribution plates of the gas distribution unit 150 may be varied. For example, the first gas distribution plate 152 may not be provided.

The dielectric member 160 may be disposed between the second and third gas distribution plates 154 and 156 and may electrically insulate the second and third gas distribution plates 154 and 156 from each other. The dielectric member 160 may include an insulating material, such as, for example, ceramic.

The shower head 130 may be disposed on the substrate processing region R4 below the third gas distribution plate 156. The shower head 130 may distribute and supply plasma from the gas mixing region R3 to the substrate processing region R4. The shower head 130 may include, for example, a distribution plate having a circular plate shape and a plurality of fourth through-holes PH4 formed in the distribution plate. The fourth through-holes PH4 may be configured to allow an etchant to pass therethrough, and the etchant may be sprayed to the substrate processing region R4 in the process chamber 110 through the fourth through-holes PH4. The shower head 130 may include a metal material, such as, for example, aluminum (Al) which may be easily machined.

The heating unit 165 may be provided around the shower head 130 to maintain the surface temperature of the shower head 130 to be constant. For example, the heating unit 165 may be disposed along the circumference of the shower head 130 or the third gas distribution plate 156, or may be disposed in the lower chamber 114 adjacent to the shower head 130. The surface temperature of the shower head 130 may be adjusted in the range of about 50° C. to about 200° C. by the heating unit 165, for example. However, in some example embodiments, the shape of the heating unit 165 and the position in which the heating unit 165 is disposed may be varied. In some example embodiments, the heating unit may include a heating element which may be include a wire coil and/or one or more conductive and/or resistive elements configured to generate heat based on a supply of electrical power thereto, for example based on electrical resistance of the heating element. In some example embodiments, the heating element of the heating unit 165 may include nichrome 80/20 wire, ribbon, or strip that is configured to generate based on receiving a supply of electrical power, such that the heating unit 165 may generate heat to control a surface temperature of the shower head 130 based on a supply of electrical power.

The first and second pumps 180 and 190 may be connected to the lower chamber 114. The first and second pumps 180 and 190 may be connected to an internal portion of the process chamber 110 through, for example, a cavity of the lower chamber 114. The first and second pumps 180 and 190 may exhaust gas including residual gas in the process chamber 110 (e.g., draw one or more gases out of the process chamber 110) through a cavity of the lower chamber 114 and may control pressure. The first and second pumps 180 and 190 may include a vacuum pump, such as, for example, a dry pump, a rotary pump, a diffusion pump, a turbo molecular pump, an ion pump, and the like. For example, the first pump 180 may include a turbo molecular pump, and the second pump 190 may include a dry pump. In this case, the first pump 180 may have an exhaust speed higher than that of the second pump 190, and may have a lower pressure range according to operation.

The first and second pressure regulators 185 and 195 may be connected to the first and second pumps 180 and 190 and may regulate pressure in the process chamber 110 by the first and second pumps 180 and 190. The first and second pressure regulators 185 and 195 may include, for example, an automatic pressure controller (APC). The valves 198 may be disposed between the first and second pumps 180 and 190 and between the second pump 190 and the second pressure regulator 195 and may control the flow of gas. However, in some example embodiments, the types of the first and second pumps 180 and 190, the first and second pressure regulators 185 and 195, and the valves 198 included in the exhaust assembly, the number of the aforementioned each component, and the arrangement forms of each component may be varied.

The coating layer 140 may cover an internal surface of the process chamber 110, a surface of the substrate support 120 exposed through the substrate processing region R4, a surface of the shower head 130, and at least a portion of surfaces of the first, second, and third gas distribution plates 152, 154, and 156. The coating layer 140 may be disposed on the surface of at least one of the components disposed below the plasma forming region R2. The coating layer 140 may be provided to increase the adsorption rate of radicals, such as, for example, fluorine (F) radicals, and accordingly, the amount of the etchant formed in the gas mixing region R3 may be secured, which will be described in greater detail below. The coating layer 140 may have a thickness in the range of about 3 μm or more, such as, for example, about 5 μm to about 30 μm.

The coating layer 140 may include, for example, an electroless plated metal layer or a non-metal layer such as quartz. When the coating layer 140 is a metal layer, the coating layer 140 may include, for example, one of nickel (Ni), copper (Cu), or stainless steel (SUS). The coating layer 140 may further include phosphorus (P).

In some example embodiments, the coating layer 140 includes phosphorus (P) and a metal element (M), and a binding energy between the metal element (M) and phosphorus (P) is less than a binding energy between the metal element (M) and fluorine (F). In some example embodiments, the coating layer 140 may include a nickel (Ni) plating layer containing phosphorus (P) (e.g., the metal element (M) is nickel (Ni)). In this case, in the coating layer 140, the binding energy between nickel (Ni) and phosphorus (P) may be lower than the binding energy between nickel (Ni) and fluorine (F), and the activation energy necessary for adsorption of fluorine (F) radicals may decrease as the content of phosphorus (P) increases. Therefore, as the content of phosphorus (P) in nickel (Ni) increases, the adsorption rate of fluorine (F) radicals may increase, thereby securing the amount or concentration of the fluorine (F₂) etchant formed from the fluorine (F) radicals.

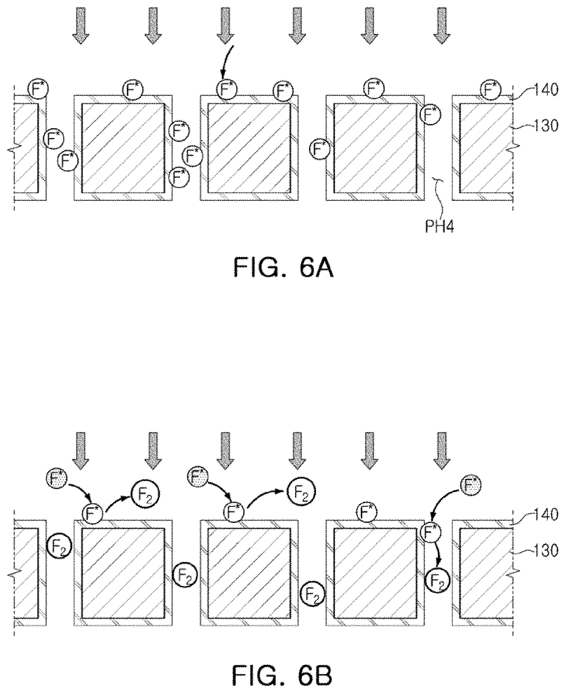

A content of the phosphorus (P) of the coating layer 140 may be in the range of about 3% to about 16%. In the example embodiments, the content of phosphorus (P) of a layer, structure, or the like may refer to an atomic percent (atomic percent, at. %) of phosphorous (P) in the layer, structure, or the like unless otherwise indicated. By adjusting the content of phosphorus (P) of the coating layer 140, an etch selectivity during processing of the substrate 10 may be adjusted, which will be described in greater detail with reference to FIGS. 6A to 8B below. When the content of phosphorus (P) of the coating layer 140 is lower than the above range, the etching ratio may not be sufficiently secured, and when the content of phosphorus (P) of the coating layer 140 is higher than the above range, the etching efficiency may be lowered.

In the substrate processing apparatus 100, when the process gas is supplied from the gas supply region R1 to the plasma forming region R2, the power supply unit 174 may apply power to the second gas distribution plate 154 and plasma may be formed in the plasma forming region R2. The plasma formed in the plasma forming region R2 may include a plurality of components. For example, the plasma may include radicals, ions, electrons, ultraviolet rays, and the like.

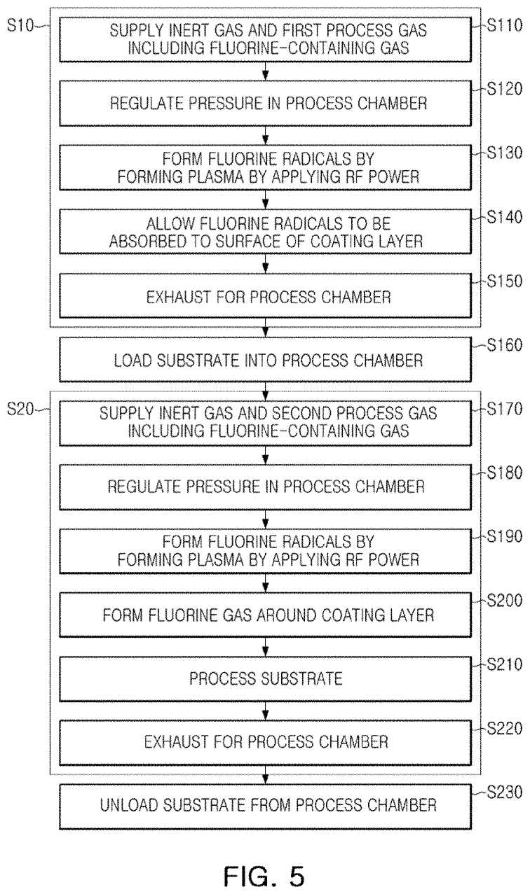

Plasma formed in the plasma forming region R2 may be supplied to the gas mixing region R3. In some example embodiments, only radicals among the components of the plasma may be provided to the gas mixing region R3, and components such as ions and electrons may be removed without being provided to the gas mixing region R3. For example, the components may be blocked without passing through the third gas distribution plate 156, but some example embodiments thereof are not limited thereto. In regions including the gas mixing region R3, provided radicals may react with radicals adsorbed to the shower head 130 and radicals may be recombined, thereby forming an etchant. The recombination of radicals may be mainly performed in the gas mixing region R3, but the region in which the recombination of radicals is performed is not limited to the gas mixing region R3. The formed etchant gas may be sprayed to the substrate processing region R4 to perform an etching process or a cleaning process for the substrate 10. The substrate processing method will be described in greater detail with reference to FIG. 5 below.

Still referring to FIGS. 1 and 2, It will be understood that the substrate processing apparatus 100 according to any of the example embodiments may be communicatively coupled to a control device, referred to herein as a substrate processing apparatus control device 900, which may be an electronic device which may be configured to control the substrate processing apparatus 100 to perform one or more operations (also referred to herein as steps and/or processes), and/or any operations, of another of the methods of manufacturing a semiconductor chip according to any of the example embodiments, including some or all operations of any of the methods shown in FIGS. 5, 10, 11A-11C, or any combination thereof.

As shown in FIG. 1, a substrate processing apparatus control device 900 may include a processor 920, a memory 930, a power supply 950 (e.g., an AC power supply device), and an interface 940 that are electrically coupled together via a bus 910. The interface 940 may be a communication interface (e.g., a wired or wireless communication transceiver).

The interface 940 is shown in FIG. 1 to be communicatively coupled with one or more portions of the substrate processing apparatus 100, but it will be understood that the interface 940, and thus the substrate processing apparatus control device 900, may be communicatively coupled with one or more portions of the substrate processing apparatus according to any of the example embodiments (e.g., any of the substrate processing apparatuses 100, 100a, 100b, 100c, 100d, 100e, and/or 1000. As shown in FIG. 1, the interface 940, and thus the substrate processing apparatus control device 900, may be communicatively (e.g., electrically) coupled with one or more portions of the substrate processing apparatus 100, including but not limited to the heating unit 165, the gas supply unit 172, the power supply unit 174, the first and second pressure regulators 185 and 195, the first and second pumps 190, and the valves 198. The substrate processing apparatus control device 900 may be configured to control (e.g., adjustably control) the operation of some, any, and/or all of the portions of the substrate processing apparatus 100 to which the substrate processing apparatus control device 900 is communicatively coupled, such that the substrate processing apparatus control device 900 may be configured to control the substrate processing apparatus 100 to cause one or more operations, steps, processes or the like according to any methods of any of the example embodiments to be performed, including for example some or all operations of any of the methods shown in FIGS. 5, 10, 11A-11C, or any combination thereof.

The memory 930 may be a non-transitory computer readable storage medium (e.g., a solid-state drive SSD) storing a program of instructions. The processor 920 (e.g., a central processing unit CPU) may be configured to execute the program of instructions stored at the memory 930 to cause one or more, or all, of the operations of any of the methods according to any of the example embodiments to be performed (e.g., based on generating a command signal and causing the command signal to be transmitted to one or more portions of the communicatively coupled substrate processing apparatus 100 via the interface 940.

In some example embodiments, the substrate processing apparatus may include an actuator, for example a servo actuator, servo arm, robotic arm, or the like which may be configured to move one or more substrates into and/or out of the substrate processing apparatus 100, for example to load one or more substrates 10 on the substrate support 120 in the process chamber 110 in the substrate processing apparatus 100, to cause one or more substrates 10 to be moved between different regions in the substrate processing apparatus 100, to unload one or more substrates from the substrate processing apparatus 100, any combination thereof, or the like.

In some example embodiments, the substrate processing apparatus 100 may include one or more additional devices configured to perform a subsequent semiconductor process (e.g., a photo process and/or an etching process), including for example an etching laser.

In some example embodiments, a substrate processing apparatus control device 900 according to any of the example embodiments may be communicatively coupled to one or more portions of the substrate processing apparatus 100, including but not limited to the heating unit 165, the gas supply unit 172, the power supply unit 174, the first and second pressure regulators 185 and 195, the first and second pumps 190, and the valves 198. The substrate processing apparatus control device 900 may be configured to (based on, for example, the processor 920 executing a program of instructions stored at the memory 730) cause one or more operations of any of the methods of the example embodiments to be performed based on generating one or more command signals and transmitting the command signals, and/or selectively and/or adjustably controlling a supply of electrical power, to one or more of the heating unit 165, the gas supply unit 172, the power supply unit 174, the first and second pressure regulators 185 and 195, the first and second pumps 190, the valves 198, or the like of the communicatively coupled substrate processing apparatus 100 to cause one or more operations to be performed based on operation of the one or more of the heating unit 165, the gas supply unit 172, the power supply unit 174, the first and second pressure regulators 185 and 195, the first and second pumps 190, and the valves 198, or the like in response to the one or more command signals.

As described herein, any devices, systems, blocks, modules, units, controllers, circuits, apparatus, and/or portions thereof according to any of some example embodiments (including, without limitation, any of the example embodiments of a substrate processing apparatus, the substrate processing apparatus control device 900, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, blocks, modules, units, controllers, circuits, apparatuses, and/or portions thereof according to any of some example embodiments, and/or any portions thereof, including for example some or all operations of any of the methods shown in FIGS. 5, 10, 11A-11C, or any combination thereof.

It will be understood that, in some example embodiments, a semiconductor device manufactured according to any of the example embodiments may be incorporated into an electronic device having similar structure as the substrate processing apparatus control device 900 shown in FIG. 1 (e.g., an electronic device, including a processor 920, memory 930, power supply 950, and/or interface 940 communicatively coupled via a bus 910 may include a semiconductor device manufactured according to any of the example embodiments, including semiconductor device 200, in any of the processor 920, memory 930, power supply 950, and/or interface 940).

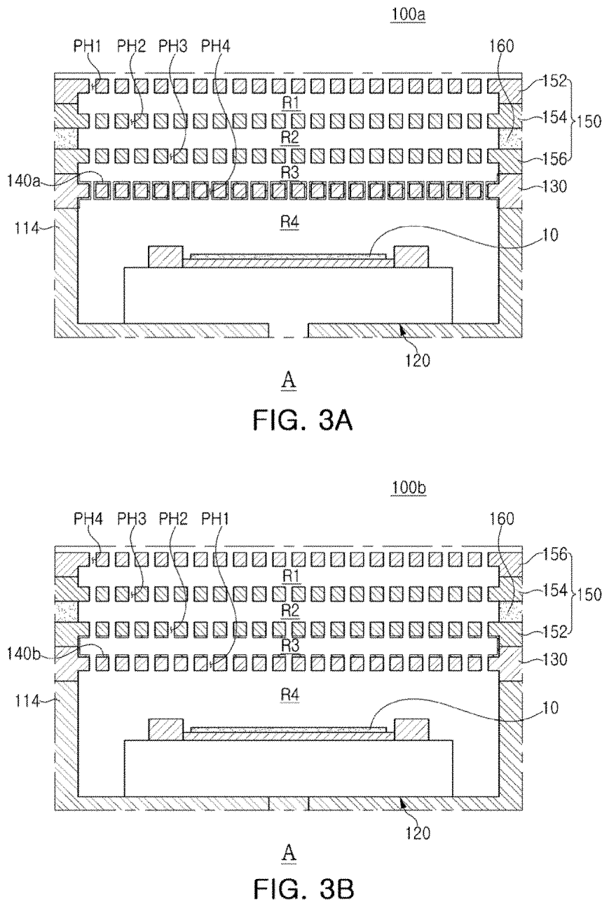

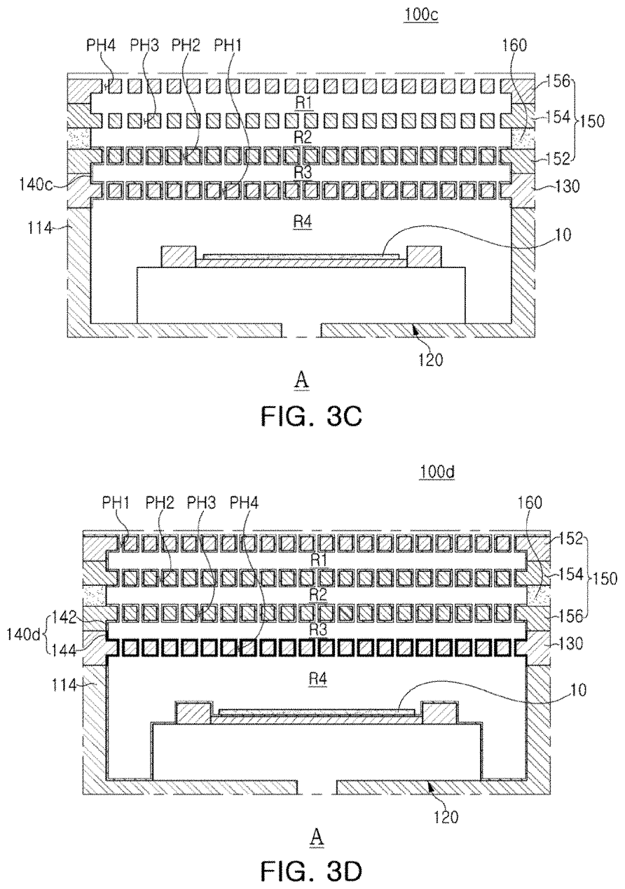

FIGS. 3A, 3B, 3C, and 3D are enlarged views illustrating a portion of a substrate processing apparatus according to some example embodiments.

Referring to FIG. 3A, in a substrate processing apparatus 100a, differently from the example embodiments in FIGS. 1 and 2, the coating layer 140a may be disposed only on the surface of the shower head 130. Since the shower head 130 may be the component through which radicals formed in the upper portion may pass through lastly, the adsorption rate of radicals on the surface of the shower head 130 may be relatively important. Accordingly, the coating layer 140a may be formed to cover the entire surface of the shower head 130. However, in some example embodiments, the coating layer 140a may cover only a portion of the surface of the shower head 130. For example, in some example embodiments, when the size of the fourth through-holes PH4 is relatively small, the coating layer 140a may not cover the internal side wall of the fourth through-holes PH4 of the shower head 130 and may only cover the upper and lower surfaces.

Also, in some example embodiments, the coating layer 140a may be further disposed on the surfaces of the process chamber 110 and the substrate support 120 exposed through the substrate processing region R4 below the shower head 130.

Referring to FIG. 3B, in a substrate processing apparatus 100b, differently from some example embodiments, including the example embodiments shown in FIG. 3A, the coating layer 140b may be disposed to cover a portion of the surface of the shower head 130 including the upper surface. Also, the coating layer 140b may be disposed to cover a portion including the lower surface of the first gas distribution plate 152 included in the gas mixing region R3 together with the shower head 130. Accordingly, the coating layer 140b may be disposed on surfaces of the shower head 130 and the first gas distribution plate 152 facing the gas mixing region R3.

Since the gas mixing region R3 is a main region in which an etchant may be formed by the recombination of radicals, an adsorption rate of radicals on the surface of the components exposed through the gas mixing region R3 may be relatively important. Accordingly, as in some example embodiments, including the example embodiments shown in FIG. 3B, the coating layer 140b may be disposed around the gas mixing region R3.

Referring to FIG. 3C, in a substrate processing apparatus 100c, differently from some example embodiments, including the example embodiments shown in FIG. 3A, the coating layer 140c may be disposed to cover only the surfaces of the shower head 130 and the first gas distribution plate 152. That is, as compared to some example embodiments, including the example embodiments shown in FIG. 3A, the coating layer 140c may be further disposed on the surface of the first gas distribution plate 152.

In some example embodiments, the coating layer 140c may be further disposed on the surfaces of the process chamber 110 and the substrate support 120 exposed through the substrate processing region R4 below the shower head 130.

Referring to FIG. 3D, in a substrate processing apparatus 100d, differently from some example embodiments, including the example embodiments shown in FIG. 2, the coating layer 140d may include first and second coating layers 142 and 144. The second coating layer 144 may cover the surface of the shower head 130, and the first coating layer 142 may cover the surfaces of the components other than the shower head 130. The first and second coating layers 142 and 144 may have different contents of phosphorus (P). For example, the content of phosphorus (P) of the first coating layer 142 may be in the range of about 3% to about 9%, and the content of phosphorus (P) of the second coating layer 144 may be in the range of about 9% to about 16%. According to this, in the shower head 130, a coating layer having a relatively high content of phosphorus (P) may be applied to secure the adsorption rate of radicals, and in the other components, a coating layer having a relatively low content of phosphorus (P) may be applied such that the decrease in the amount of etching due to the adsorption of the material including radicals may be reduced.

As in the example embodiments in FIGS. 3A to 3C, the coating layers 140a, 140b, and 140c may be disposed around the shower head 130 and the gas mixing region R3, and the coating layers 140a, 140b, and 140c may be further disposed in the other regions as in some example embodiments, including the example embodiments shown in FIGS. 1 and 2. Also, as in some example embodiments, including the example embodiments shown in FIG. 3D, the coating layer 140d may be disposed to have different content of phosphorus (P) on the surface of the shower head 130 and the surfaces of the other components. For example, in the region in which the coating layer is not disposed in the example embodiments in FIGS. 3A to 3C, a coating layer having a relatively low content of phosphorus (P) may be further disposed.

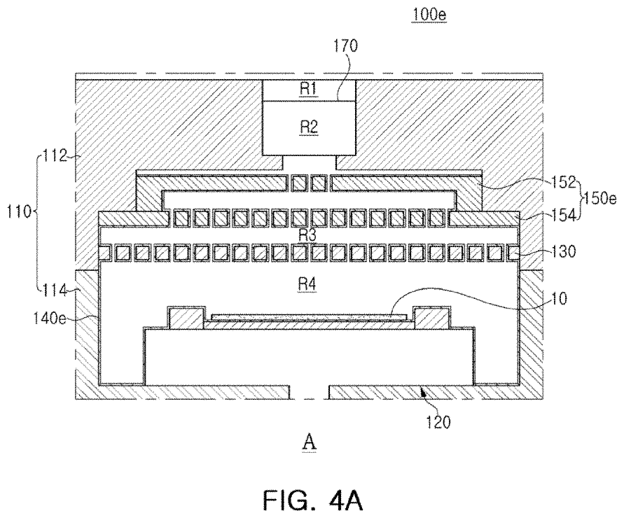

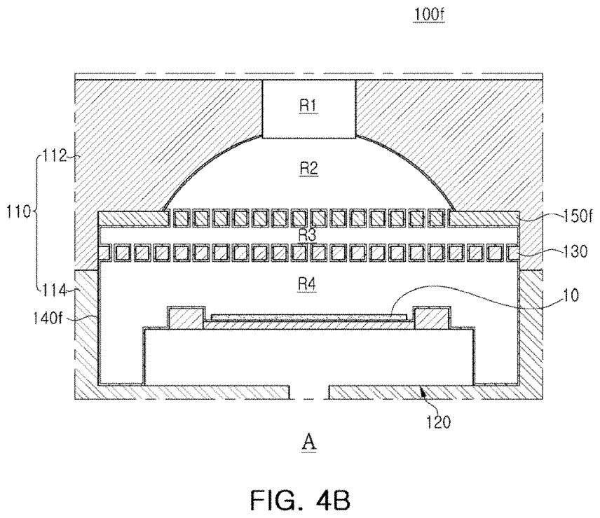

FIGS. 4A and 4B are cross-sectional views illustrating a substrate processing apparatus according to some example embodiments. In FIGS. 4A and 4B, only main components of the substrate processing apparatus are shown illustrating a region corresponding to the portion “A” in FIG. 1.

Referring to FIG. 4A, a substrate processing apparatus 100e may be configured to use a remote plasma source (RPS) method. The substrate processing apparatus 100e may include a plasma generator 170 forming (e.g., including a set of inner surfaces that at least partially define) a plasma forming region R2, and may include a gas distributor 150e including first and second gas distribution plates 152 and 154.

The plasma generator 170 (also referred to herein interchangeably as a plasma forming unit) may include a pair of electrodes therein, and may form plasma in the plasma forming region R2 between the electrodes using the gas supplied from the gas supply region R1. In the gas distributor 150e (also referred to as a gas distribution unit), the first and second gas distribution plates 152 and 154 may be disposed such that centers thereof may be vertically spaced apart from each other, and each of the first and second gas distribution plates 152 and 154 may have through-holes. In some example embodiments, including the example embodiments shown in FIG. 4A, the gas mixing region R3 may correspond to a region between the plasma generator 170 and the shower head 130.

The coating layer 140e may be disposed to cover an internal surface (e.g., one or more surfaces, one or more inner surfaces, etc.) of the process chamber 110, a surface of the substrate support 120 exposed through the substrate processing region R4, a surface of the shower head 130, and at least a portion of the surfaces of the first and second gas distribution plates 152 and 154. However, in some example embodiments, the arrangement form of the coating layer 140e may be varied as described above in a range in which the coating layer 140e may cover at least a portion of the surface of the shower head 130.

Referring to FIG. 4B, the substrate processing apparatus 100f may be configured to use an inductively coupled plasma (ICP) method. In the substrate processing apparatus 100f, plasma may be formed in the plasma forming region R2 by a coil surrounding the plasma forming region R2. The coil may be disposed in the upper chamber 112 or externally of the upper chamber 112. The substrate processing apparatus 100f may include a gas distribution unit 150f. In some example embodiments, including the example embodiments shown in FIG. 4B, the gas distribution unit 150f may include a single gas distribution plate, but the configuration of the gas distribution unit 150f is not limited thereto.

The coating layer 140f may be disposed to cover an internal surface of the process chamber 110, a surface of the substrate support 120 exposed through the substrate processing region R4, a surface of the shower head 130, and at least a portion of the surface of the gas distribution unit 150f. However, in some example embodiments, the arrangement form of the coating layer 140f may be varied as described above in a range in which the coating layer 140f may cover at least a portion of the surface of the shower head 130.

As in the example embodiments in FIGS. 4A and 4B, the coating layers 140e and 140f may be applied to the substrate processing apparatuses 100e and 100f using various plasma methods.

FIG. 5 is a flowchart illustrating a substrate processing method according to some example embodiments. The substrate processing method will be described with reference to the substrate processing apparatus in FIGS. 1 and 2.

FIGS. 6A and 6B are views illustrating a substrate processing method according to some example embodiments.

Referring to FIGS. 1, 2, and 5, the substrate processing method may include a pre-processing process S10 and a main process S20. The pre-processing process S10 may be performed, and the substrate 10 may be loaded in the process chamber 110 (S160), and thereafter, the main process S20 may be performed, and the substrate 10 may be unloaded from the process chamber 110 (S230). Accordingly, the pre-processing process S10 may be performed in the process chamber 110 before the substrate 10 is put into.

The pretreatment process S10 may include a process of supplying an inert gas and a first process gas containing a fluorine-containing (S110), a process of regulating internal pressure of the process chamber 110 (S120), a process of applying RF power to generate plasma to generate fluorine radicals (S130), a process of allowing fluorine radicals to be absorbed to the surface of the coating layer 140 (S140), and a process of exhausting for the process chamber 110 (S150).

Specifically, the inert gas and the first process gas including a fluorine-containing gas may be supplied from the gas supply unit 172 into the process chamber 110 (S110). The first process gas may be, for example, at least one of NF₃, SiF₆, or CF₄. After supplying the gases, the amount of exhaust by the first and second pumps 180 and 190 may be controlled by regulating the first and second pressure regulators 185 and 195 and the valves 198, such that the internal pressure of the process chamber 110 may be adjusted to a target pressure (S120). The target pressure may be in the range of, for example, several Torr to several tens of Torr.

Thereafter, by applying RF power by the power supply unit 174, plasma may be formed in the plasma forming region R2 such that fluorine radicals may be formed (S130). In this process, for example, a large amount of fluorine radicals may be formed using high-frequency power. The formed fluorine radicals may be partially adsorbed on the surface of the coating layer 140 while moving toward the exhaust unit according to the internal flow of the process chamber 110 (S140). Fluorine radicals may be adsorbed to the plasma forming region R2 and the surface of the coating layer 140 disposed therebelow. As illustrated in FIG. 6A, for example, fluorine radicals may be adsorbed to the coating layer 140 on the surface of the shower head 130. The adsorption rate of fluorine radicals to the coating layer 140 may be controlled by the content of phosphorus (P) in the coating layer 140. Residual radicals and residual gases not adsorbed to the surface of the coating layer 140 may be exhausted (e.g., drawn out of the process chamber 110) by the first and second pumps 180 and 190 (S150).

The main process S20 may be performed after the substrate 10 is put into the process chamber 110 (S160). The main process S20 may include a process of supplying an inert gas and a second process gas including a fluorine-containing gas (S170), a process of regulating internal pressure of the process chamber 110 (S180), a process of forming fluorine radicals by forming plasma by applying RF power (S190), a process of forming a fluorine gas around the coating layer 140 (S200), a process of processing the substrate 10 using the fluorine gas (S210), and a process of exhausting for (e.g., drawing one or more gasses out of) the process chamber 110.

Specifically, the inert gas and the second process gas including the fluorine-containing gas may be supplied from the gas supply unit 172 into the process chamber 110 (S170). The second process gas may be, for example, at least one of NF₃, SiF₆, or CF₄. After supplying the gases, by controlling the amount of exhaust (e.g., amount of gas(es) drawn out of the process chamber 110) by the first and second pumps 180 and 190 by regulating the first and second pressure regulators 185 and 195 and the valves 198, the internal pressure of 110 may be adjusted to a target pressure (S180). The target pressure may be in the range of, for example, several Torr to several tens of Torr.

Thereafter, by forming plasma in the plasma forming region R2 by applying RF power by the power supply unit 174, fluorine radicals may be formed (S190). In this process, for example, a large amount of fluorine radicals may be formed using high-frequency power. The formed fluorine radicals may move according to the internal flow of the process chamber 110, and may be combined, around the coating layer 140, with the fluorine radicals adsorbed to the surface of the coating layer 140 in the process S140, thereby forming a fluorine gas (F₂) (S200). As illustrated in FIG. 6B, for example, fluorine radicals may be combined with fluorine radicals adsorbed to the coating layer 140 and fluorine gas (F₂) may be formed. The fluorine gas (F₂) may be formed in and below the plasma forming region R2. The fluorine gas (F₂) may be mainly formed in the gas mixing region R3, but some example embodiments thereof is not limited thereto.

Thereafter, the substrate 10 may be treated using fluorine gas (F₂) as an etchant (S210). For example, when the substrate 10 includes a first SiGe layer including a low concentration germanium (Ge) and a second SiGe layer including a high concentration germanium (Ge), the second SiGe layer may be selectively etched and removed with respect to the first SiGe layer. When fluorine gas (F₂) is directly supplied as an etchant, fluorine gas (F₂) may corrode the gas transfer path in the substrate processing apparatus 100 such that the substrate 10 may be contaminated. However, by using the substrate processing methods in the example embodiments, fluorine gas (F₂) may be used as an etchant without directly supplying the fluorine gas (F₂). After the etching process is performed, the remaining gases may be exhausted (e.g., drawn out of the process chamber 110) by the first and second pumps 180 and 190 (S220).

When performing the pre-treatment process S10 and the main process S20, at least a portion of the components, such as, for example, the surface temperature of the shower head 130 or the coating layer 140 may be maintained in the range of about 50° C. to about 200° C., such as, for example, about 90° C. to about 110° C., by the heating unit 165. The fluorine (F₂) generation rate may be determined according to the surface temperature of the coating layer 140, and the fluorine (F₂) generation rate may significantly increase in the above temperature range.

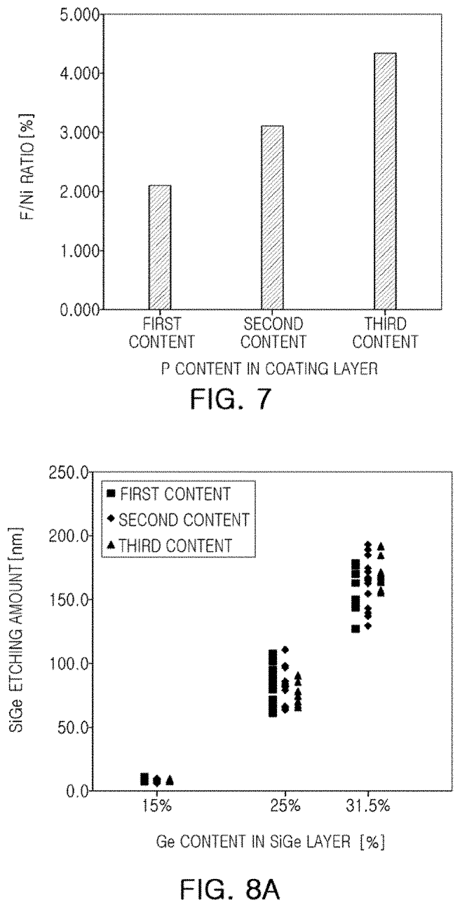

FIG. 7 is a graph illustrating a substrate processing method according to some example embodiments.

FIG. 7 illustrates a surface analysis result of the coating layer by X-ray photoelectron, spectroscopy (XPS). The coating layer used for the analysis was a nickel layer, and the analysis was performed for the case in which the content of phosphorus (P) in the coating layer was first to third contents. The first to third contents were 4.4%, 7.3%, and 13.9%, respectively. The ratio (F/Ni) of fluorine element to nickel element was measured to be 2.1, 3.1, and 4.4, respectively, on the surfaces of the coating layers having the first to third contents of phosphorus (P). Accordingly, it is indicated that, when the phosphorus content in the nickel coating layer increases, the concentration of fluorine radicals adsorbed to the surface of the coating layer may also increase linearly.

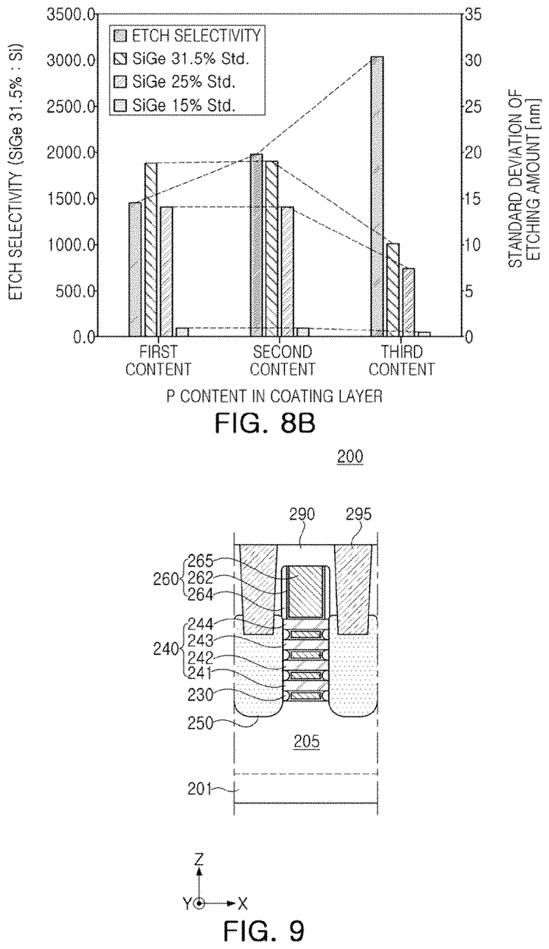

FIGS. 8A and 8B are graphs illustrating a substrate processing method according to some example embodiments.

FIGS. 8A and 8B illustrate results of analysis of etching amount, etch selectivity, and process reproducibility in the case of etching SiGe thin film layers using the substrate processing method described in some example embodiments. The thin film layers used for processing the substrate may have contents of germanium (Ge) of 15.0%, 25.0%, and 31.5%, respectively. In the case of the substrate processing apparatus, the substrate processing apparatus 100d as illustrated in FIG. 3D was used. The analysis was performed using a nickel layer containing about 7.3% of phosphorus (P) was used for the coating layer, and using a nickel layer having phosphorus (P) of the first to third contents for the shower head. The first to third content of phosphorus (P) was about 4.4%, about 7.3%, and about 13.9%, respectively. The heating unit 165 (see FIG. 1) was determined to be at 100° C., and the substrate support 120 (see FIG. 1) was maintained at 5° C.

As illustrated in FIG. 8A, in the overall cases in which the nickel layer having the first to third content of phosphorus (P) is applied as the coating layer, the amount of etching of the thin film layer increased as the germanium content in the SiGe thin film layer increased.

FIG. 8B illustrates the etch selectivity. In the case of the etch selectivity to the silicon (Si) layer, the calculation was carried out using the etching amount for the SiGe layer having a germanium (Ge) content of 15.0%, 25.0%, and 31.5%. As illustrated in FIG. 8B, as the content of phosphorus (P) increased, etch selectivity of 31.5% of SiGe with respect to Si increased, which may be because, as the content of phosphorus (P) in the coating layer increased, the amount of the formed fluorine gas (F₂) etchant increased.

Table 1 below lists the etch selectivity of the SiGe layer containing 31.5% of germanium (Ge) with respect to each of the Si layer and the SiGe layer containing 10% of germanium (Ge), and the etch selectivity was analyzed according to the content of phosphorus (P) in the coating layer. The etch ratio of SiGe 31.5%:Si was as high as about 3044 (e.g., 3044.3:1, shown in Table 1 as 3044.3) when a coating layer having the third content of phosphorus (P) is used, and the etch selectivity value was more than twice that of a case in which the first content of phosphorus (P) is used. The etch ratio of SiGe 31.5%:SiGe 10% increased from 95 to 148.6 as the phosphorus content increases, such that the etch ratio improved more than 1.5 times.

TABLE 1
SiGe etch selectivity according to content of phosphorus (P)
in coating layer of shower head

| | First P | Second P | Third P |
|---|---|---|---|
| Etch selectivity | content | content | content |
| (etch ratio) | (about 4.4%) | (about 7.3%) | (about 13.9%) |
| SiGe 31.5%: Si | 1452 | 1974.5 | 3044.3 |
| SiGe 31.5%: SiGe 10% | 95 | 109.6 | 148.6 |

Table 2 lists the standard deviation of the SiGe etching amount (e.g., in nm) according to the content of phosphorus (P) in the coating layer of the shower head. Referring to Table 2 and FIG. 8B, as the content of phosphorus (P) in the coating layer increased, the standard deviation of the etching amount decreased. As compared with the case in which the content of phosphorus (P) was the first content, the standard deviation was reduced by about 44% or more when the content of phosphorus (P) was the third content. The reduced standard deviation may indicate high process reproducibility. The result of process reproducibility may indicate that, when the content of phosphorus (P) is relatively high, the recombination rate of fluorine radicals may increase, such that the etchant concentration may be maintained to be more constant. Also, the maintaining the pressure in the process chamber to be constant using the plurality of pumps including the first pump 180 (see FIG. 1) having a relatively high exhaust speed, such as a turbo molecular pump, may further improve process reproducibility.

TABLE 2
Standard deviation of SiGe etching amount according to content
of phosphorus (P) in coating layer of shower head

| | First P | Second P | Third P |
|---|---|---|---|
| Standard | content | content | content |
| deviation (nm) | (about 4.4%) | (about 7.3%) | (about 13.9%) |
| SiGe 15.0% | 1.1 | 1.1 | 0.5 |
| SiGe 25.0% | 14.1 | 14.2 | 7.5 |
| SiGe 31.5% | 18.9 | 19.1 | 10.2 |

According to the above results, when a SiGe layer having a high germanium (Ge) content needs to be selectively etched with respect to the Si layer, a coating layer having a high content of phosphorus (P) may be applied to a shower head. To sufficiently secure the etch selectivity and process reproducibility, phosphorus (P) may be contained in the coating layer in the range of about 3% to about 16%, such as, for example, in the range of about 9% to about 16%. When the radical adsorption rate is high, however, the amount of etching per hour may be reduced, and accordingly, for a process in which it is important to secure the amount of etching per hour, the content of phosphorus (P) in the coating layer may be regulated to be relatively low.

FIG. 9 is a cross-sectional view illustrating a semiconductor device manufactured using a substrate processing apparatus and a substrate processing method according to some example embodiments.

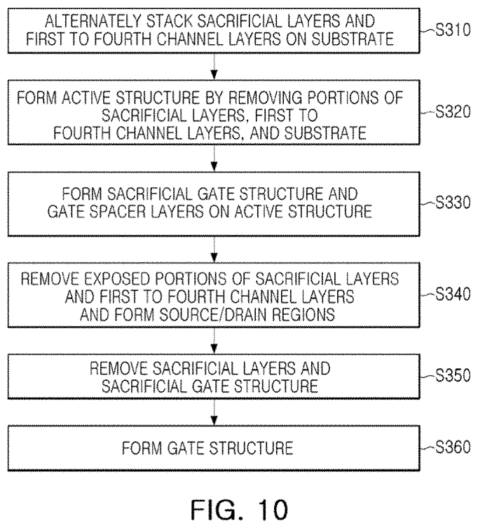

FIG. 10 is a flowchart illustrating a method of manufacturing a semiconductor device according to some example embodiments.

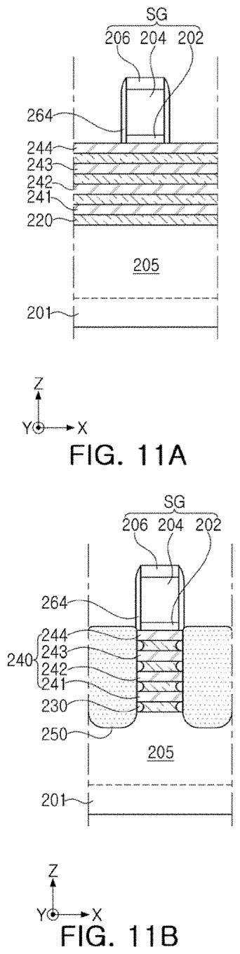

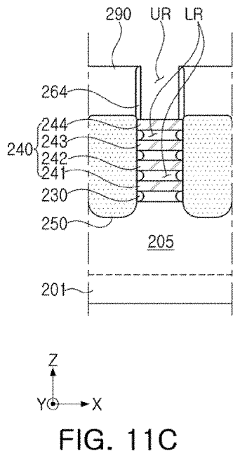

FIGS. 11A, 11B, and 11C are views illustrating processes of a method of manufacturing a semiconductor device in order according to some example embodiments.

Referring to FIG. 9, a semiconductor device 200 may include a substrate 201, an active region 205 on the substrate 201, channel structures 240 including first to fourth channel layers 241, 242, 243, 244 (241-244) vertically spaced apart from each other, a gate structure 260 including a gate electrode 265 extending while intersecting the active regions 205, source/drain regions 250 in contact with the first to fourth channel layers 241-244, and contact plugs 295 connected to the source/drain regions 250. The semiconductor device 200 may further include a device isolation layer, internal spacer layers 230, a gate dielectric layer 262, gate spacer layers 264, and an interlayer insulating layer 290.

In the semiconductor device 200, the active region 205 may have a fin structure, and the gate electrode 265 may be disposed between the active region 205 and the channel structures 240, between the first to fourth channel layers 241-244 of the channel structures 240, and above the channel structures 240. Accordingly, the semiconductor device 200 may include a transistor having a multi-bridge channel FET (MBCFET™) structure, which is a gate-all-around type field effect transistor.

Referring to FIG. 10, the method of manufacturing the semiconductor device 200 may include a process of alternately stacking the sacrificial layers 220 (see FIG. 11A) and the first to fourth channel layers 241-244 on the substrate 201 (S310), a process of forming an active structure by removing portions of the sacrificial layers 220, the first to fourth channel layers 241-244, and the substrate 201 (S320), a process of forming a sacrificial gate structure SG (see FIG. 11A) and gate spacer layers 264 on the active structure (S330), a process of removing portions of the exposed sacrificial layers 220 and the first to fourth channel layers 241-244, and forming source/drain regions 250 (S340), and a process of forming the gate structure 260 (S360).

Among the above processes, in the process of removing the sacrificial layers 220 (S350), the substrate processing apparatus and the substrate processing method according to the example embodiments may be used. Accordingly, the method of manufacturing the semiconductor device will be described with reference to the above process.

Referring to FIG. 11A, the sacrificial layers 220 and the first to fourth channel layers 241-244 may be alternately stacked on the substrate 201 (S310), an active structure may be formed by removing a portion of the substrate 201 (S320), and a sacrificial gate structure SG and gate spacer layers 264 may be formed on the active structure (S330).

The sacrificial layers 220 may be replaced by the gate dielectric layer 262 and the gate electrode 265 as illustrated in FIG. 9 through a subsequent process. The sacrificial layers 220 may be formed of a material having etch selectivity with respect to the first to fourth channel layers 241-244, respectively. In some example embodiments, the sacrificial layers 220 may include silicon germanium (SiGe) having a first germanium (Ge) concentration, and the first to fourth channel layers 241-244 may include germanium (SiGe) having a second germanium (Ge) concentration lower than the first germanium (Ge) concentration, or silicon (Si). For example, the first germanium (Ge) concentration may be in the range of about 28 at. % to about 35 at. %.

The active structures may include the sacrificial layers 220 and the first to fourth channel layers 241-244 alternately stacked with each other, and may further include the active regions 205 formed to protrude from the substrate 201 by removing a portion of the substrate 201. The active structures may be formed in a linear shape extending in one direction, such as, for example, the x-direction.

The sacrificial gate structure SG may be configured as a sacrificial structure formed in a region of the upper portion of the channel structures 240 in which the gate dielectric layer 262 and the gate electrode 265 are disposed through a subsequent process as illustrated in FIG. 9. The sacrificial gate structure SG may include first and second sacrificial gate layers 202 and 204 and a mask pattern layer 206 stacked in order. The sacrificial gate structure SG may extend, for example, in a y-direction.

Referring to FIG. 11B, the sacrificial layers 220 and the first to fourth channel layers 241-244 may be partially removed, and the source/drain regions 250 may be formed (S340).

A portion of the exposed sacrificial layers 220 and the first to fourth channel layers 241-244 may be removed using the sacrificial gate structure SG and the gate spacer layers 264 as masks, thereby forming recess regions. The sacrificial layers 220 exposed through the recess regions may be partially removed from side surfaces and internal spacer layers 230 may be formed. The source/drain regions 250 may be formed by growing from the active regions 205 and side surfaces of the channel structures 240, by a selective epitaxial process, for example.

Referring to FIG. 11C, the sacrificial layers 220 and the sacrificial gate structure SG may be removed (S350).

Firstly, an interlayer insulating layer 290 covering the sacrificial gate structure SG and the source/drain regions 250 may be formed. The sacrificial layers 220 and the sacrificial gate structure SG may be selectively removed with respect to the gate spacer layers 264, the interlayer insulating layer 290, the channel structures 240, and the internal spacer layers 230. Firstly, upper gap regions UR may be formed by removing the sacrificial gate structure SG, and lower gap regions LR may be formed by removing the sacrificial layers 220 exposed through the upper gap regions UR.

In particular, the sacrificial layers 220 may be selectively etched with respect to the first to fourth channel layers 241-244 having a high germanium (Ge) concentration. The etching process may be performed using the substrate processing apparatus including the coating layer described above with reference to FIGS. 1 to 4B and may be performed by the substrate processing method described above with reference to FIG. 5. The content of phosphorus (P) of the coating layer may be, for example, in the range of about 6 at. % to about 16 at. %, such as, for example about 9 at. % to about 16 at. %. Accordingly, the sacrificial layers 220 may be removed with a high etch selectivity while being removed by dry etching.

Thereafter, referring to FIG. 10, a gate structure 260 may be formed (S360), and contact plugs 295 may be formed.

By forming the gate dielectric layer 262 and the gate electrode 265 to fill the upper gap regions UR and the lower gap regions LR, the gate structure 260 may be formed. The contact plugs 295 may be formed by forming contact holes exposing the source/drain regions 250 by patterning the interlayer insulating layer 290, and filling the contact holes with a conductive material. Accordingly, the semiconductor device 200 in FIG. 10 may be manufactured.

According to the aforementioned example embodiments, the substrate processing apparatus having improved etch selectivity and the substrate processing method using the same may be provided.

While some example embodiments have been illustrated and described above, it will be apparent to those skilled in the art that modifications and variations could be made without departing from the scope of the present inventive concepts as defined by the appended claims.

1. A substrate processing apparatus, comprising:
a first set of inner surfaces that at least partially define a plasma forming region, wherein the substrate processing apparatus is configured to form a plasma within the plasma forming region;
a second set of inner surfaces that at least partially define a gas supply region, wherein the substrate processing apparatus is configured to supply a process gas from the gas supply region to the plasma forming region;
a third set of inner surfaces that at least partially define a gas mixing region, wherein the substrate processing apparatus is configured to form an etchant in the gas mixing region based on recombination of radicals supplied from the plasma forming region to the gas mixing region;
a fourth set of inner surfaces that at least partially define a substrate processing region, wherein the substrate processing apparatus is configured to process a substrate based on the etchant within the substrate processing region;
a shower head between the gas mixing region and the substrate processing region, the shower head configured to supply the etchant to the substrate processing region;
a coating layer covering a surface of the shower head, the coating layer including nickel (Ni) containing phosphorus (P); and
a heater configured to control a surface temperature of the shower head.

2. The substrate processing apparatus of claim 1, wherein a content of phosphorus (P) of the coating layer is in a range of about 3 at. % to about 16 at. %.

3. The substrate processing apparatus of claim 1, wherein the shower head includes aluminum (Al).

4. The substrate processing apparatus of claim 1, wherein the radicals are fluorine radicals, and the etchant is fluorine (F₂).

5. The substrate processing apparatus of claim 1, further comprising:
a gas distribution plate between the plasma forming region and the gas mixing region and configured to supply the radicals to the gas mixing region; and
a plate coating layer covering a surface of the gas distribution plate and including nickel (Ni) containing phosphorus (P).

6. The substrate processing apparatus of claim 5, wherein the coating layer and the plate coating layer have different contents of phosphorous (P), and a first content of phosphorus (P) of the coating layer is higher than a second content of phosphorus (P) of the plate coating layer.

7. The substrate processing apparatus of claim 6, wherein the first content of phosphorus (P) is in a range of about 9 at. % to about 16 at. %.

8. The substrate processing apparatus of claim 1, further comprising:
a process chamber surrounding the substrate processing region; and
a chamber coating layer covering an internal surface of the process chamber and including nickel (Ni) containing phosphorus (P).

9. The substrate processing apparatus of claim 1, wherein the heater is configured to control the surface temperature of the shower head to be a temperature in a range of about 50° C. to about 200° C.

10. The substrate processing apparatus of claim 1, wherein the process gas is at least one of NF₃, SiF₆, or CF₄.

11. A substrate processing apparatus, comprising:
a first set of inner surfaces that at least partially define a plasma forming region, wherein the substrate processing apparatus is configured to form a plasma within the plasma forming region;
a second set of inner surfaces that at least partially define a gas mixing region, wherein the substrate processing apparatus is configured to form an etchant in the gas mixing region based on recombination of radicals supplied from the plasma forming region to the gas mixing region;
a third set of inner surfaces that at least partially define a substrate processing region, wherein the substrate processing apparatus is configured to process a substrate based on the etchant within the substrate processing region;
a shower head between the gas mixing region and the substrate processing region, the shower head configured to supply the etchant to the substrate processing region; and
a coating layer covering at least a portion of a surface of the shower head, the portion of the surface of the shower head including an upper surface of the shower head, the coating layer containing phosphorus (P).

12. The substrate processing apparatus of claim 11, wherein the coating layer is formed of phosphorus (P) and nickel (Ni).

13. The substrate processing apparatus of claim 11, wherein the radicals are fluorine radicals, and the etchant is fluorine (F₂).

14. The substrate processing apparatus of claim 13, wherein
the coating layer includes phosphorus (P) and a metal element (M), and
a binding energy between the metal element (M) and phosphorus (P) is less than a binding energy between the metal element (M) and fluorine (F).

15. The substrate processing apparatus of claim 11, wherein the upper surface of the shower head faces the gas mixing region.

16. The substrate processing apparatus of claim 11, further comprising:
a gas distribution plate between the plasma forming region and the gas mixing region,
wherein the coating layer covers a lower surface of the gas distribution plate facing the gas mixing region and the upper surface of the shower head facing the gas mixing region.

17. A substrate processing apparatus, comprising:
a process chamber including one or more sets of inner surfaces that at least partially define a plasma processing space within the process chamber;
a gas supply configured to supply gas into the process chamber;
a power supply configured to form a plasma in the process chamber;
a substrate support member located in the process chamber, the substrate support member configured to support a substrate in the process chamber;
a shower head on the substrate support member in the process chamber;
at least one gas distribution plate on the shower head in the process chamber; and
a coating layer covering at least a portion of one or more surfaces of the shower head, the at least one gas distribution plate, and the process chamber, the coating layer including nickel (Ni) containing phosphorus (P).

18. The substrate processing apparatus of claim 17, wherein the coating layer is below a region of the process chamber in which the power supply is configured to form the plasma.

19. The substrate processing apparatus of claim 17, further comprising:
a heater that is adjacent to the shower head, the heater configured to adjust a surface temperature of the shower head.

20. The substrate processing apparatus of claim 17, further comprising:
a plurality of vacuum pumps connected to the process chamber, the plurality of vacuum pumps configured to draw gas out of the process chamber.

21. (canceled)

22. (canceled)

23. (canceled)

24. (canceled)
